(19) United States
(12) Patent Application Publication
(10) Pub. No.: US 2009/0258319 A1
(43) Pub. Date: Oct. 15, 2009

(54) EXPOSURE METHOD AND SEMICONDUCTOR DEVICE MANUFACTURING METHOD

(76) Inventors: Satoshi NAGAI, Kawasaki-shi (JP); Kazuya Fukuhara, Tokyo (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/423,595

(22) Filed: Apr. 14, 2009

(30) Foreign Application Priority Data
Apr. 15, 2008 (JP) 2008-106057

(51) Int. Cl. G03F 7/20

(52) U.S. Cl. 430/319; 430/322

(57) ABSTRACT

In an exposure method, an anti-reflection film and a photoresist are stacked in order on the surface of a substrate. A periodic pattern of a pitch P is formed on a pattern surface of a photomask. A medium having a refractive index n is present between a projection lens having a numerical aperture NAp and the substrate. The refractive index, coefficient of extinction and thickness of the anti-reflection film are selected so that the reflectance of exposure light of a wavelength λ at an interface between the photoresist and the anti-reflection film is less than or equal to a desired value when an angle of incidence θ is within a range determined by λ/P−NAp≦n×sin θ≦NAp. The angle of incidence θ is formed to a perpendicular line in the medium by light incident on the surface of the substrate.

### CROSS-REFERENCE TO RELATED APPLICATIONS

This application is based upon and claims the benefit of priority from prior Japanese Patent Application No. 2008-106057, filed Apr. 15, 2008, the entire contents of which are incorporated herein by reference.

### BACKGROUND OF THE INVENTION

1. Field of the Invention

The present invention relates to an exposure method and a semiconductor device manufacturing method. More particularly, the present invention relates to a lithographic technique included in one of the steps of manufacturing a semiconductor device.

2. Description of the Related Art

In a lithographic step using semiconductor exposure tools, a circuit pattern of a photomask is imaged on the photoresist applied to a substrate with appropriate designs of an illumination optical system, the photomask and a projection optical system. Then, the photoresist pattern is transferred to the substrate by an etching step.

If light is reflected at the resist-bottom interface during exposure in the lithographic step, standing waves are created in the photoresist. This makes the circuit pattern on the photoresist not faithful to the one that has been expected. Thus, an anti-reflection film is usually applied between the photoresist and the substrate to ensure faithfulness of the circuit pattern (see, for example, Jpn. Pat. Appln. KOKAI Publication No. 2006-73709).

In the above-mentioned document, the reflectance at the resist-bottom interface is required to be less than or equal to a predetermined value through the incident angle of exposure light ranged between 0° to the maximum angle determined by the exposure tools. However, such an anti-reflection film is often not sufficient for the formation of a micro circuit pattern having a half-pitch less than or equal to the wavelength of the exposure light. The reason is as follows: The anti-reflection film has to not only prohibit reflection but also serve as a mask material in the etching of a substrate just under this anti-reflection film. However, it should be noted that if the anti-reflection function comes closer to the ideal, there is less choice of material. Therefore, when forming a micro circuit pattern that often needs excellent anti-reflection function, it gets more difficult to cover an etching function. This is the reason why the authors regard the anti-reflection film provided by the above-mentioned invention as insufficient.

In the meantime, in the exposure of some photomasks there is often a case where the angle range of exposure light associated with imaging is not as wide as the one mentioned above. It is the case when the kind of circuit patterns is limited. Here, we needn't consider unnecessary range of incident angle in the designing of the anti-reflection film.

### BRIEF SUMMARY OF THE INVENTION

According to a first aspect of the present invention, there is provided an exposure method comprising applying, to a photomask, exposure light of a wavelength λ emitted from an effective light source in an illumination optical system, and projecting the light through the photomask onto a substrate via a projection lens having a numerical aperture NAp, an anti-reflection film and a photoresist being stacked in order on the surface of the substrate, a periodic pattern of a pitch P being formed on a pattern surface of the photomask, a medium having a refractive index n being present between the projection lens and the substrate, wherein the refractive index, coefficient of extinction and thickness of the anti-reflection film are selected so that the reflectance of the exposure light of the wavelength λ at an interface between the photoresist and the anti-reflection film is less than or equal to a desired value when an angle of incidence θ is within a range determined by Equation 1 or so that the reflectance of the exposure light of the wavelength λ at the interface between the photoresist and the anti-reflection film is less than or equal to the desired value when the angle of incidence θ is equal to an angle of incidence determined by Equation 2, the angle of incidence θ being formed to a perpendicular line in the medium by light incident on the surface of the substrate on which the photoresist is formed,

λ/P−NAp≦n×sin θ≦NAp (1)

sin θ=λ/2nP (2).

According to a second aspect of the present invention, there is provided an exposure method comprising applying, to a photomask, exposure light of a wavelength λ emitted from an effective light source in an illumination optical system, and projecting the light through the photomask onto a substrate via a projection lens having a numerical aperture NAp, an anti-reflection film and a photoresist being stacked in order on the surface of the substrate, a periodic pattern of a pitch P being formed on a pattern surface of the photomask, a medium having a refractive index n being present between the projection lens and the substrate, wherein the refractive index, coefficient of extinction and thickness of the anti-reflection film are selected so that the reflectance of the exposure light of the wavelength λ at an interface between the photoresist and the anti-reflection film is less than or equal to a desired value when an angle of incidence θ is within a range common to a range determined by Equation 3 and to a predetermined range determined by an illumination condition, the angle of incidence θ being formed to a perpendicular line in the medium by light incident on the surface of the substrate on which the photoresist is formed,

λ/P−NAp≦n×sin θ≦NAp (3).

According to a third aspect of the present invention, there is provided a semiconductor device manufacturing method which includes a process using an exposure method, the exposure method including applying, to a photomask, exposure light of a wavelength λ emitted from an effective light source in an illumination optical system, and projecting the light through the photomask onto a substrate via a projection lens having a numerical aperture NAp, an anti-reflection film and a photoresist being stacked in order on the surface of the substrate, a periodic pattern of a pitch P being formed on a pattern surface of the photomask, a medium having a refractive index n being present between the projection lens and the substrate, wherein the refractive index, coefficient of extinction and thickness of the anti-reflection film are selected so that the reflectance of the exposure light of the wavelength λ at an interface between the photoresist and the anti-reflection film is less than or equal to a desired value when an angle of incidence θ is within a range determined by Equation 4 or so that the reflectance of the exposure light of the wavelength λ at the interface between the photoresist and the anti-reflection film is less than or equal to the desired value when the angle of incidence θ is equal to an angle of incidence determined by Equation 5, the angle of incidence θ being formed to a perpendicular line in the medium by light incident on the surface of the substrate on which the photoresist is formed,

λ/P−NAp≦n×sin θ≦NAp (4)

sin θ=λ/2nP (5).

### BRIEF DESCRIPTION OF THE SEVERAL VIEWS OF THE DRAWING

FIG. 1 is a flowchart shown to explain an example of an exposure method according to a first embodiment of the present invention;

FIG. 2 is a diagram showing a periodic pattern on a photomask;

FIG. 3 is a schematic diagram showing an example of the configuration of an exposure apparatus;

FIGS. 4A and 4B are diagrams shown to explain the relationship between the traveling direction of exposure light incident on the photomask and the directions of the oscillating electric field for s-polarization and p-polarization;

FIG. 5 is a diagram showing an example of the configuration of a dipole illumination;

FIG. 6 is a diagram showing the configuration of films on a work substrate;

FIG. 7 is a graph showing the reflectance characteristics of the exposure light at the interface between a photoresist and an intermediate film; and

FIGS. 8A and 8B are graphs showing resist-bottom reflectance where the angle of incidence of the exposure light and the thickness of an intermediate film serve as parameters, according to a second embodiment of the present invention.

### DETAILED DESCRIPTION OF THE INVENTION

Embodiments of the present invention will be described with reference to the accompanying drawings. It should be noted that the drawings are schematic ones and so are not to scale. The following embodiments are directed to a device and a method for embodying the technical concept of the present invention and the technical concept does not specify the material, shape, structure or configuration of components of the present invention. Various changes and modifications can be made to the technical concept without departing from the scope of the claimed invention.

### First Embodiment

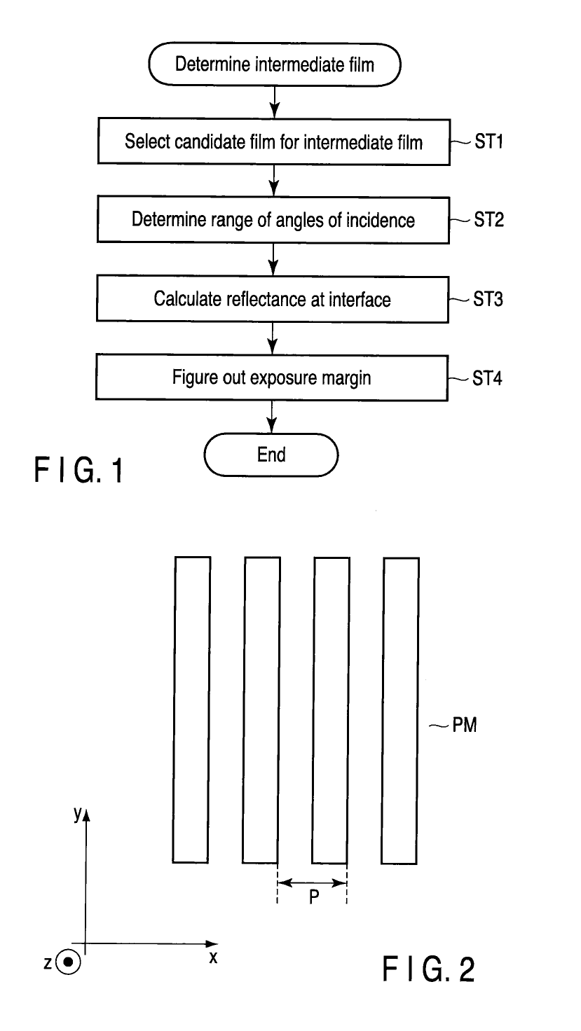

FIG. 1 shows an example of an exposure method according to a first embodiment of the present invention. Described in the present embodiment is a method of designing an anti-reflection film which is used in the manufacture of, for example, a NAND flash memory and which is suitable for the formation of a micropattern by light exposure.

In this embodiment, we assume that a coating-type intermediate film is applied under a photoresist as an anti-reflection film. It is designed in accordance with the kind of a circuit pattern to be transferred. It is also assumed that a photomask, which has a line-and-space pattern (periodic pattern) PM with a pitch P of 88 nm as shown in FIG. 2, is exposed to light under the conditions described below.

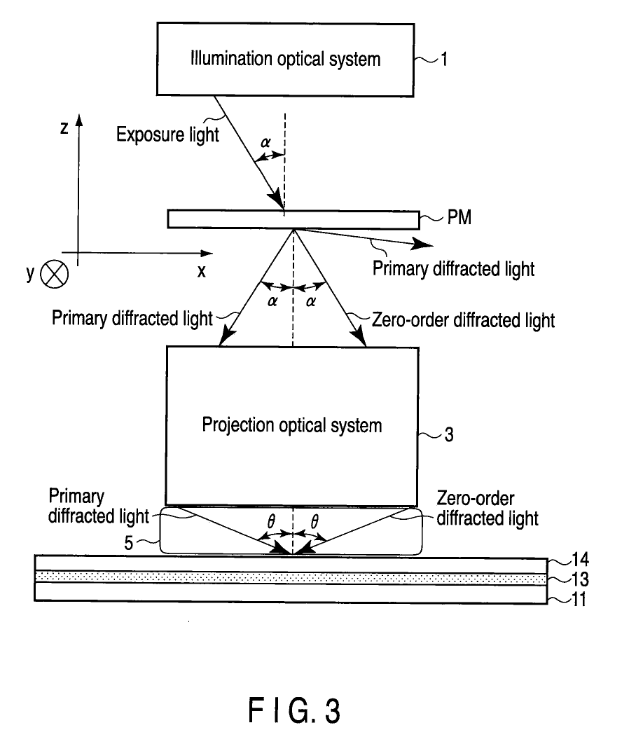

FIG. 3 shows the configuration of an exposure apparatus used for exposure. This exposure apparatus applies exposure light with the wavelength λ being 193 nm emitted from an effective light source plane within an illumination optical system 1 to the photomask PM, and projects the light through the photomask PM onto a work substrate 11 via a projection lens (projection optical system) 3 with the numerical aperture NAp being 1.3. A photoresist 14 is formed on the surface of the work substrate 11. An anti-reflection film 13 is formed between the work substrate 11 and the photoresist 14. Water, having a refractive index n of 1.437, is applied to the medium 5 between the projection lens 3 and the work substrate 11 as an immersion liquid.

In the present condition, the k1 factor as represented by Equation 6 is 0.29 and less than 0.5.

k1=P×NAp/(2λ) (6)

In general, when the k1 factor is less than 0.5, at most two of the light components different in the order of diffraction are only permitted to enter the projection lens 3, out of light diffracted by the periodic pattern on the photomask PM. However, in order to transfer the periodic pattern to the work substrate 11, a minimum of two light components different in the order of diffraction need to enter the projection lens 3. This is enabled by tilting the exposure light. FIG. 3 shows the traveling paths (optical paths) of light components inclined a from an optical axis (indicated by a broken line in the diagram) out of the exposure light, and shows how the zero-order diffracted light and the primary diffracted light, out of the light diffracted by the photomask PM, enter the projection lens 3. The incidence angle of exposure light (zero-order diffracted light) to a perpendicular line (indicated by a broken line) in the medium 5 is expressed with θ. The incidence angle of diffracted light to a perpendicular line depends on θ. The figure shows a special case when the incidence angle of first-order diffracted light (primary diffracted light) is the same as that of zero-order diffracted light.

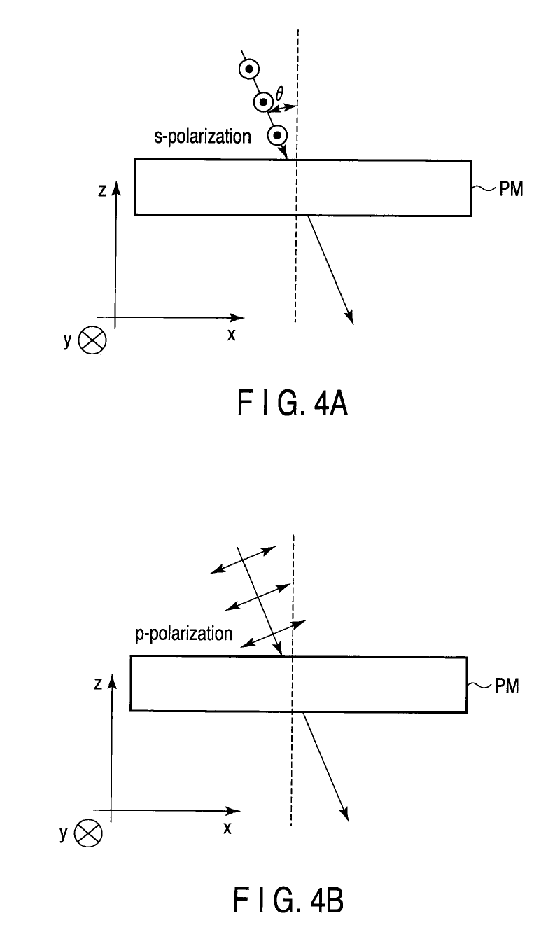

Furthermore, the exposure light is assumed to be the one in which the vibration direction of its electric vector is perpendicular to the plane of incidence on the photoresist 14. Practically, the degree of polarization of illumination light (exposure light) is assumed to be 0.9 (s-polarization accounts for 90%, p-polarization accounts for 10%). In addition, the relationship between the traveling direction of the exposure light incident on the photomask PM and the vibration direction of the electric field for s-polarization and p-polarization are as shown in FIGS. 4A and 4B.

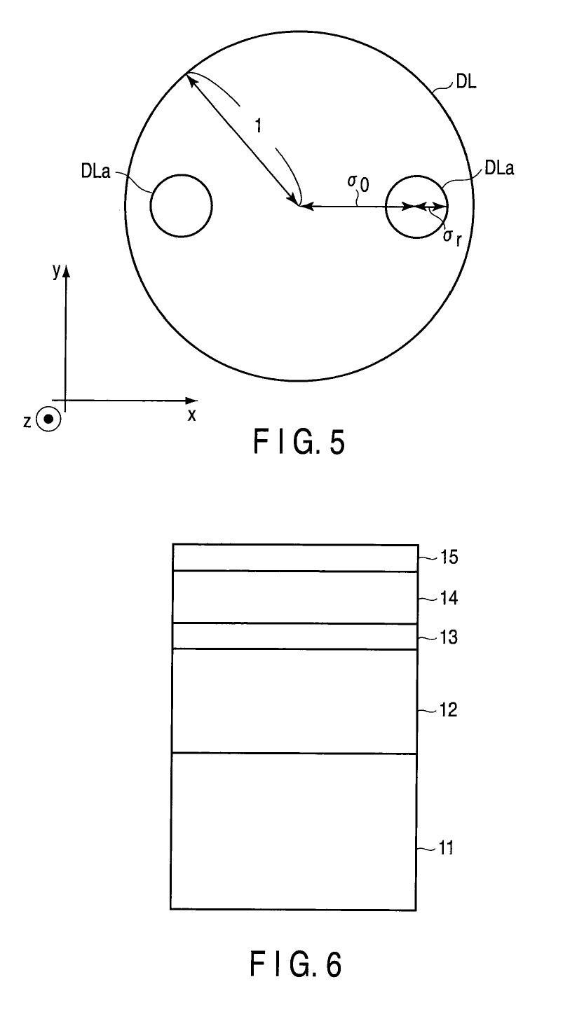

FIG. 5 shows an example of the configuration of the illumination optical system 1. In the present embodiment, a dipole illumination DL is used as the illumination optical system 1. The central positions of two poles denoted as DLa are specified with σo. The σo value is set to an optimum value derived by the following equation, σo=λ/(2×P×NAp). It should be noted that the σo value is determined by the pitch P of the periodic pattern. Further, the radius of the pole DLa is specified with σr, which is a predetermined value.

FIG. 6 shows the configuration of films on the work substrate 11 in more detail. A lower film 12, the intermediate film (anti-reflection film) 13, the photoresist 14 and a protective film 15 are stacked in order from the bottom on the surface of the work substrate 11 to be exposed. The surface of the work substrate 11 is made of silicon (Si). The lower film 12 has a complex refractive index n-ik, wherein n is 1.36, and k is 0.42. The lower film 12 has a thickness d of 230 nm. The intermediate film 13 has a thickness d of 45 nm. The photoresist 14 has a complex refractive index n-ik, wherein n is 1.69, and k is 0.03. The photoresist 14 has a thickness d of 100 nm. The protective film 15 has a complex refractive index n-ik, wherein n is 1.52. The protective film 15 has a thickness d of 90 nm.

The refractive index, coefficient of extinction and thickness of the intermediate film 13 are selected so that the reflectance of the exposure light of the wavelength λ at the interface between the photoresist 14 and the intermediate film 13 may be less than or equal to a predetermined value when the angle of incidence θ of light incident on the work substrate 11 to the perpendicular line in the medium 5 is within a predetermined range of angles of incidence determined by Equation 7 with respect to the pitch P of the periodic pattern.

λ/P−NAp≦n×sin θ≦NAp (7)

Equation 7 provides a range of incidence angle of exposure light in the medium 5 associated with imaging. This formula is effective when the k1 factor is less than 0.5. In the present case, the angles of incidence of light which can be associated with imaging in principle to the photoresist 14 range from 38.4° to 64.8° under the above-mentioned λ, n, P, NAp. The reflectance at the interface between the intermediate film 13 and the photoresist 14 within the above range of angles of incidence may be represented by the maximum value or average value within this angle range.

By assuming the exposure condition mentioned above, a method of determining the intermediate film 13 is specifically described with reference to FIG. 1.

First, a candidate material for the intermediate film 13 is selected from materials which may serve as etching materials for the lower film 12, and its complex refractive index is measured (step ST1).

Then, the angle range of incidence light associated with imaging is determined (step ST2).

Then, reflectance at the interface between the photoresist 14 and the intermediate film 13 is calculated, and reflectance within the above range of angles of incidence is found. It should be noted that the calculation here takes into account a multiple interference which occurs when light enters the stacked films (step ST3).

Then, the exposure margin is evaluated and it is examined whether there is enough exposure margin or not. When there is enough, the material for the intermediate film 13 is fixed. When there isn't enough, another candidate for intermediate film 13 is prepared to start again from ST1 (step ST4).

The method described above provides conditions for the intermediate film 13 to have an exposure margin enabling mass production. As a result, for example, when the material of the intermediate film 13 needs to be changed, whether an exposure margin enabling mass production is obtained can be known in advance by measuring the complex refractive index of a material.

The following results were obtained when a material of the intermediate film 13 was actually selected in accordance with the above-described procedure.

For example, there were two candidate materials for the intermediate film 13; an “intermediate film candidate 1” and an “intermediate film candidate 2”. The complex refractive index of the “intermediate film candidate 1” includes n=1.62 and k=0.10. The complex refractive index of the “intermediate film candidate 2” includes n=1.58 and k=0.17.

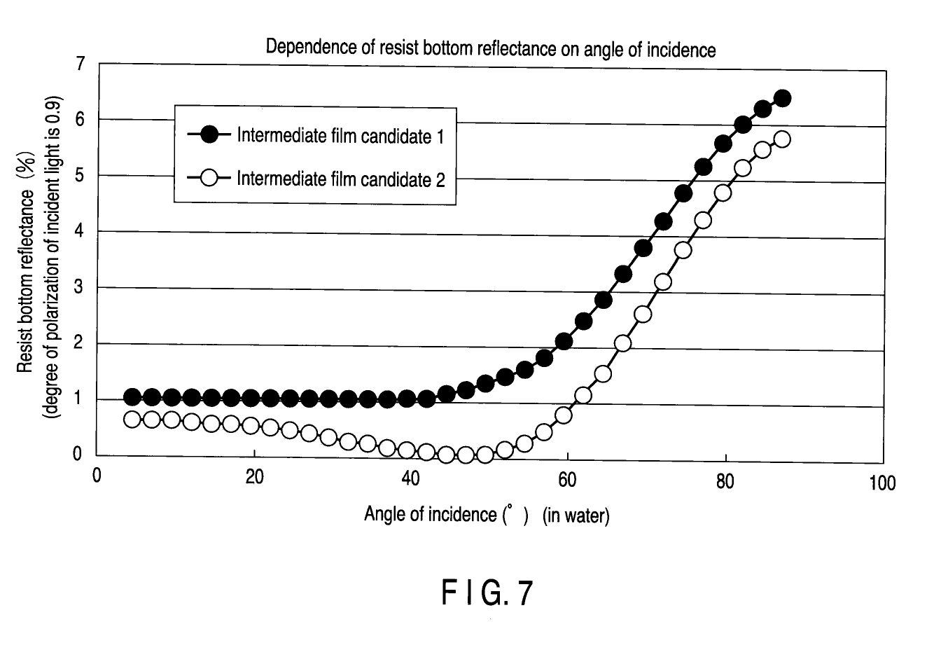

Calculations of reflectance at the interface between the photoresist 14 and the intermediate film 13 are as shown in FIG. 7. In accordance with the graph in FIG. 7, the average value and maximum value (both converted to values in water) of reflectance within the above range of angles of incidence were 1.57% and 2.81% for the “intermediate film candidate 1”, and 0.38% and 1.5% for the “intermediate film candidate 2”.

The intermediate films 13 were formed by the “intermediate film candidate 1” and the “intermediate film candidate 2”, and actually exposed. Necessary resist dimensional accuracy was not obtained for the “intermediate film candidate 1”, while necessary resist dimensional accuracy was obtained for the “intermediate film candidate 2”.

Thus, a lithographic step and an etching step using the “intermediate film candidate 2” for the intermediate film 13 were formulated. Moreover, it was found out that a material of the intermediate film 13 should have an average value and a maximum value of reflectance within the range of angles of incidence below 1.0% and 2.0%, respectively. Consequently, when the material of the intermediate film 13 needs to be changed, whether a material can be actually applied to the intermediate film 13 can be judged by the calculation of reflectance as described above.

According to the present embodiment, an intermediate film suitable for the formation of a micropattern by light exposure can be designed. That is, an intermediate film can be designed to have anti-reflection characteristics (function) that can sufficiently inhibit reflection from the underlayer of the photoresist within the range of angles of incidence of light corresponding to the kind of circuit pattern in the photomask to be exposed. As a result, the formation of standing waves in the photoresist can be inhibited, and a circuit pattern as expected in designing can be formed. Moreover, a range of angles of incidence to provide the anti-reflection function is determined. Thus, for example, there are no longer unnecessary limitations of the material of the intermediate film, and at the same time, latitude can be provided to the selection of a material satisfying etching resistance. It is therefore possible to easily achieve both the anti-reflection characteristics and the etching resistance. Hence, when such an exposure method is used for the manufacture of a semiconductor device such as a NAND flash memory, a smaller semiconductor device can be manufactured.

In addition, the periodic pattern of the pitch P has only to be present in at least one place on the pattern surface of the photomask PM.

### Application 1 of First Embodiment

The refractive index, coefficient of extinction and thickness of the intermediate film 13 may be selected so that, instead of the reflectance within the range of angles of incidence determined by Equation 7, reflectance represented by Equation 8 at a particular angle of incidence θ determined in accordance with the pitch P of the periodic pattern may be less than or equal to a predetermined value.

sin θ=λ/2nP (8)

Equation 8 defines the angle of incident light that can provide the most satisfactory imaging characteristics when the periodic pattern is transferred under conditions at a k1 factor of less than 0.5. This corresponds to the case where the angles of incidence in the medium 5 of the zero-order diffracted light and the primary diffracted light that are diffracted by the photomask PM are equal as shown in FIG. 3. In general, the illumination shape of the illumination optical system 1 is designed so that this incidence angle θ may be included. Therefore, it is also possible to design the intermediate film 13 only using the reflectance at the angle of incidence θ as an index. If the values of λ, n, P in the first embodiment are used as they are, the angle of incidence θ is 49.8° in accordance with Equation 8. Reflectance at the interface between the photoresist 14 and the intermediate film 13 at an angle of incidence of 49.8° is 1.2% for the “intermediate film candidate 1”, and 0.04% for the “intermediate film candidate 2”.

When exposure was actually performed as in the first embodiment, it was found out that the reflectance should not be beyond 1% at an angle of incidence of 49.8°. Thus it was found that “intermediate film candidate 2” is appropriate.

### Application 2 of First Embodiment

In the first embodiment described above, when the pitch P of the periodic pattern is 88 nm, “0.843” is selected as the optimum value for the σ value (σO) that determines the central position of the pole DLa of the dipole illumination DL, and “0.15” is selected as the σ value (σr) that determines the radius of the pole DLa. In this case, angles of incidence of light associated with imaging to the photoresist 14 range from 44.1° to 56.2°, which is narrower than an angular range of 38.4° to 64.8° determined by Equation 7. Thus, under this illumination condition, the refractive index, coefficient of extinction and thickness of the intermediate film 13 need to be selected so that reflectance may be less than or equal to a predetermined value within an angular range of 44.1° to 56.2°.

In the present example, the average value and maximum value were 1.31% and 1.57% for the “intermediate film candidate 1”, and 0.09% and 0.294% for the “intermediate film candidate 2”.

When exposure was actually performed as in the first embodiment, it was found out that the average value and maximum value of the reflectance of the intermediate film 13 should not be beyond 1.0% and 1.5%. Thus it was found that “intermediate film candidate 2” is appropriate.

### Second Embodiment

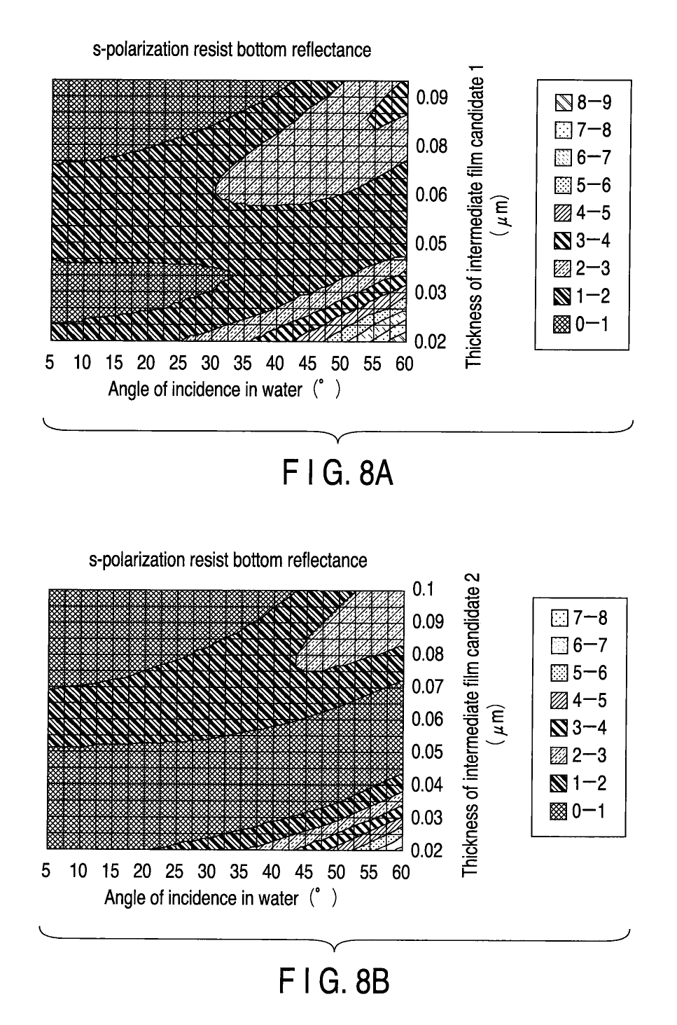

In the present embodiment, it is assumed that the incidence angle θ is ranged from 0° to 30°, which is a range common to that determined by Equation 6 and that determined by an illumination condition. FIGS. 8A and 8B shows the resist bottom reflectance of s-polarization exposure with regard to the incidence angle in water and the thickness of the intermediate film when the “intermediate film candidate 1” and “intermediate film candidate 2” as mentioned in the first embodiment are applied as the materials of the intermediate film 13. It is apparent from the graphs in FIGS. 8A and 8B that if the thickness is appropriately set, the reflectance in the “intermediate film candidate 1” and the reflectance in “intermediate film candidate 2” are both less than or equal to 1% within the range of angles of incidence of 0° to 30°. Therefore, the manufacturer can choose any one of these two candidates. It may be the one with lower cost or the one with better etching performance.

Letting the one with lower cost be the “intermediate film candidate 1”, the thickness is determined as follows: A condition imposed by the photoresist 14 and the lower film 12 on the intermediate film 13 requires that the thickness of the intermediate film 13 be at least 30 nm or more in connection with the etching resistance of the lower film 12. Similarly, the thickness of the intermediate film 13 needs to be at most 60 nm in connection with the etching resistance of the photoresist 14. Since it is desirable to choose the condition with lower reflectance, it has been ascertained that the thickness of the intermediate film candidate 1 should be about 35 nm in accordance with the graphs.

When such an exposure method is used for the manufacture of a semiconductor device such as a NAND flash memory, a smaller semiconductor device can be manufactured with a low cost.

Moreover, in the present embodiment as well, the periodic pattern has only to be present in at least one place on the pattern surface of the photomask.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. An exposure method comprising applying, to a photomask, exposure light of a wavelength λ emitted from an effective light source in an illumination optical system, and projecting the light through the photomask onto a substrate via a projection lens having a numerical aperture NAp,
an anti-reflection film and a photoresist being stacked in order on the surface of the substrate,
a periodic pattern of a pitch P being formed on a pattern surface of the photomask,
a medium having a refractive index n being present between the projection lens and the substrate,
wherein the refractive index, coefficient of extinction and thickness of the anti-reflection film are selected so that the reflectance of the exposure light of the wavelength λ at an interface between the photoresist and the anti-reflection film is less than or equal to a desired value when an angle of incidence θ is within a range determined by Equation 9 or so that the reflectance of the exposure light of the wavelength λ at the interface between the photoresist and the anti-reflection film is less than or equal to the desired value when the angle of incidence θ is equal to an angle of incidence determined by Equation 10, the angle of incidence θ being formed to a perpendicular line in the medium by light incident on the surface of the substrate on which the photoresist is formed,
λ/P−NAp≦n×sin θ≦NAp (9)
sin θ=λ/2nP (10).

2. The exposure method according to claim 1, wherein a k1 factor represented by Equation 11 is less than 0.5 in the periodic pattern of the pitch P,
k1=P×NAp/(2λ) (11).

3. The exposure method according to claim 1, wherein the exposure light includes more light perpendicular to an plane of incidence where the vibration direction of an electric vector enters the photoresist than light parallel to the plane of incidence where the vibration direction of the electric vector enters the photoresist.

4. The exposure method according to claim 1, wherein a dipole illumination which uses the numerical aperture NAp of the projection lens as a unit and which has a circular shape with a radius of “1” is used for the illumination optical system, the radius of the effective light source being σr in the dipole illumination, a distance σo from the center of the dipole illumination to the central position of the effective light source being provided by Equation 12,
σo=λ/(2×P×NAp) (12).

5. The exposure method according to claim 1, further comprising:
measuring the complex refractive index of the selected anti-reflection film;
determining a range of angles at which light associated with imaging enters the photoresist;
calculating reflectance at the interface between the photoresist and the anti-reflection film and finding reflectance within the above range of angles of incidence; and
actually performing exposure to find an exposure margin enabling mass production.

6. The exposure method according to claim 1, wherein the periodic pattern of the pitch P is present in at least one place on the pattern surface of the photomask.

7. An exposure method comprising applying, to a photomask, exposure light of a wavelength λ emitted from an effective light source in an illumination optical system, and projecting the light through the photomask onto a substrate via a projection lens having a numerical aperture NAp,
an anti-reflection film and a photoresist being stacked in order on the surface of the substrate,
a periodic pattern of a pitch P being formed on a pattern surface of the photomask,
a medium having a refractive index n being present between the projection lens and the substrate,
wherein the refractive index, coefficient of extinction and thickness of the anti-reflection film are selected so that the reflectance of the exposure light of the wavelength λ at an interface between the photoresist and the anti-reflection film is less than or equal to a desired value when an angle of incidence θ is within a range common to a range determined by Equation 13 and to a predetermined range determined by an illumination condition, the angle of incidence θ being formed to a perpendicular line in the medium by light incident on the surface of the substrate on which the photoresist is formed,
λ/P−NAp≦n×sin θ≦NAp (13).

8. The exposure method according to claim 7, wherein a k1 factor represented by Equation 14 is less than 0.5 in the periodic pattern of the pitch P,
k1=P×NAp/(2λ) (14).

9. The exposure method according to claim 7, wherein the exposure light includes more light perpendicular to an plane of incidence where the vibration direction of an electric vector enters the photoresist than light parallel to the plane of incidence where the vibration direction of the electric vector enters the photoresist.

10. The exposure method according to claim 7, wherein a dipole illumination which uses the numerical aperture NAp of the projection lens as a unit and which has a circular shape with a radius of “1” is used for the illumination optical system, the radius of the effective light source being σr in the dipole illumination, a distance σo from the center of the dipole illumination to the central position of the effective light source being provided by Equation 15,
σo=λ/(2×P×NAp) (15).

11. The exposure method according to claim 7, further comprising:
measuring the complex refractive index of the selected anti-reflection film;
determining a range of angles at which light associated with imaging enters the photoresist;
calculating reflectance at the interface between the photoresist and the anti-reflection film and finding reflectance within the above range of angles of incidence; and
actually performing exposure to find an exposure margin enabling mass production.

12. The exposure method according to claim 7, wherein the periodic pattern of the pitch P is present in at least one place on the pattern surface of the photomask.

13. A semiconductor device manufacturing method which includes a process using an exposure method, the exposure method including applying, to a photomask, exposure light of a wavelength λ emitted from an effective light source in an illumination optical system, and projecting the light through the photomask onto a substrate via a projection lens having a numerical aperture NAp,
an anti-reflection film and a photoresist being stacked in order on the surface of the substrate,
a periodic pattern of a pitch P being formed on a pattern surface of the photomask,
a medium having a refractive index n being present between the projection lens and the substrate,
wherein the refractive index, coefficient of extinction and thickness of the anti-reflection film are selected so that the reflectance of the exposure light of the wavelength λ at an interface between the photoresist and the anti-reflection film is less than or equal to a desired value when an angle of incidence θ is within a range determined by Equation 16 or so that the reflectance of the exposure light of the wavelength λ at the interface between the photoresist and the anti-reflection film is less than or equal to the desired value when the angle of incidence θ is equal to an angle of incidence determined by Equation 17, the angle of incidence θ being formed to a perpendicular line in the medium by light incident on the surface of the substrate on which the photoresist is formed,
λ/P−NAp≦n×sin θ≦NAp (16)
sin θ=λ/2nP (17).

14. The semiconductor device manufacturing method according to claim 13, wherein a k1 factor represented by Equation 18 is less than 0.5 in the periodic pattern of the pitch P,
k1=P×NAp/(2%) (18).

15. The semiconductor device manufacturing method according to claim 13, wherein the exposure light includes more light perpendicular to an plane of incidence where the vibration direction of an electric vector enters the photoresist than light parallel to the plane of incidence where the vibration direction of the electric vector enters the photoresist.

16. The semiconductor device manufacturing method according to claim 13, wherein a dipole illumination which uses the numerical aperture NAp of the projection lens as a unit and which has a circular shape with a radius of “1” is used for the illumination optical system, the radius of the effective light source being σr in the dipole illumination, a distance σo from the center of the dipole illumination to the central position of the effective light source being provided by Equation 19,
σo=λ/(2×P×NAp) (19).

17. The semiconductor device manufacturing method according to claim 13, wherein the exposure method further includes:
measuring the complex refractive index of the selected anti-reflection film;
determining a range of angles at which light associated with imaging enters the photoresist;
calculating reflectance at the interface between the photoresist and the anti-reflection film and finding reflectance within the above range of angles of incidence; and
actually performing exposure to find an exposure margin enabling mass production.

18. The semiconductor device manufacturing method according to claim 13, wherein the periodic pattern of the pitch P is present in at least one place on the pattern surface of the photomask.
